(19) United States
(12) Patent Application Publication
(10) Pub. No.: US 2010/0294362 A1
(43) Pub. Date: Nov. 25, 2010

(54) Temperature-Control Body for Photovoltaic Modules

(75) Inventors: Martin Christ, Augsburg (DE); Oswin Öttinger, Meitingen (DE); Dirk Heuer, Augsburg (DE)

Correspondence Address: LERNER GREENBERG STEMER LLP, P O BOX 2480, HOLLYWOOD, FL, 33022-2480, US

(73) Assignee: SGL CARBON SE, Wiesbaden (DE)

(21) Appl. No.: 12/741,601

(22) PCT Filed: Nov. 6, 2008
(86) PCT No.: PCT/EP2008/065070

§ 371 Date: Aug. 10, 2010

(30) Foreign Application Priority Data
Nov. 6, 2007 (DE) 10 2007 053 225.5

(51) Int. Cl. H01L 31/024; C01B 31/04

(52) U.S. Cl. 136/259; 423/448

(57) ABSTRACT

Temperature-control bodies for photovoltaic modules have heat transfer tubes embedded in a layer of compressed expanded graphite and connected to the surface of a photoelectric cell layer that faces away from the solar radiation. A layered composite semi-finished product has a layer of compressed expanded graphite with a density of between 0.02 g/cm3 and 0.5 g/cm3.

The invention relates to a temperature-control body for photovoltaic modules and to semifinished products for producing this component.

Photovoltaic modules and photovoltaic systems assembled from them are used for the direct conversion of sunlight into electrical power. Special semiconductors, such as solar silicon, zinc sulfide (ZnS) or gallium arsenide (GaAs), in which electrons are released by the impingement of photons, known as photocells, are used for this purpose. The efficiency of such photovoltaic systems is strongly dependent on the amount of incident light and on the temperature of the photocells that are arranged in a photocell layer. The thermal recombination of released electrons limits the temperature range available for energy generation to a maximum of about 70° C. In particular in regions with high levels of sunshine between the 45th parallels north and south, photovoltaic modules are easily heated to temperatures of over 70° C.

The document DE 199 23 196 A1 discloses a photovoltaic device in which at least one cooling device flowed through by liquid is arranged in front of the photocell layer with regard to the direction of radiation. The cooling device is intended in this case to increase the yield of electrical energy by limiting the temperature of the photocells to a maximum of 50° C. and by the optical filtering effect of the cooling liquid that is used and of the transparent enclosing materials for the useful spectral range of sunlight. The overall efficiency is thereby improved by using the thermal energy absorbed by the cooling medium.

The document DE 10 2004 043 205 A1 describes a photovoltaic element which is provided with a temperature control. The temperature control takes place in this case by means of a temperature sensor, which is attached to the photocell, and a temperature-control body, which is fastened to the rear side or underside of the photocell and preferably flowed through by liquid. The temperature removal is intended in this case to take place by way of the temperature-control medium.

In the article “Thermal and electrical performance of a concentrating PV/Thermal collector: results from the ANU CHAPS collector” by J. S. Coventry et al., Proceedings of Solar 2002, Australian and New Zealand Solar Energy Society, conference paper, Newcastle, Australia, a description is given of a combined heat and power generating solar system in which sunlight is deflected by the aid of a parabolic, reflective channel onto a photovoltaic module provided along the line of focus. The photovoltaic module comprises a photocell layer fastened to a carrier of aluminum. The carrier has on its rear side a receptacle for a copper tube through which water flows, for carrying away the thermal energy, in order to keep the photocells in the temperature range of approximately 65° C. and at the same time use the thermal energy collected. The advantage of the sunlight being concentrated by mirrors onto the surface of the photovoltaic module is that the yield of electrical energy is higher than in the case of non-concentrating systems for the same surface area of the photovoltaic module. On the other hand, the concentration of the sunlight leads to even higher temperatures in the photovoltaic module, and consequently to lower efficiency in the conversion of radiation energy into electrical energy.

The object of the present invention is to provide a temperature-control body for photovoltaic modules which makes it possible to facilitate the heat transfer between the absorption area and the heat transfer liquid. The photovoltaic modules equipped with the temperature-control body according to the invention can be used both in non-concentrating systems (flat collectors) and in systems in which the incident solar radiation is concentrated onto the surface of the photovoltaic modules by mirrors, lenses or similar devices. Furthermore, use of the heat removed from the photovoltaic module in the temperature-control body according to the invention is possible.

This object is achieved by heat transfer tubes 3 through which temperature-control medium 2 flows being embedded in a layer 4 of compressed expanded graphite and connected to the surface of a photocell layer 1 that is facing away from the solar irradiation. The embedding of the heat transfer tubes 3 in compressed expanded graphite has the effect that the entire surface of the tube is available for heat transfer, and therefore the heat transfer resistance is significantly reduced. Compressed expanded graphite is understood as meaning an expanded graphite compacted under the effect of pressure, with a density of between 0.02 g/cm³ and 0.5 g/cm³. Further advantageous refinements are presented in claims 2 to 13.

A further object is that of providing a semifinished product which can be used, inter alia, for producing the temperature-control body according to the invention. According to the invention, this object is achieved by the laminar semifinished product comprising a layer 4 of compressed expanded graphite with a density of between 0.02 g/cm³ and 0.5 g/cm³. Advantageous refinements of the semifinished product are specified in claims 15 and 16. The advantages, details and variants of the invention are evident from the following detailed description and the figures.

In the figures:

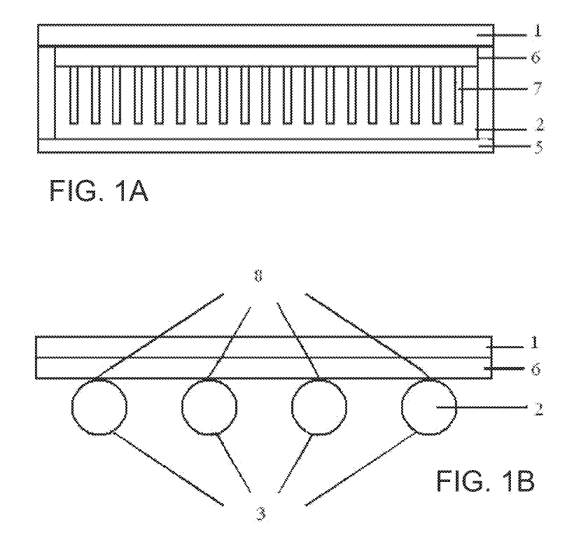

FIGS. 1a and b show temperature-control bodies for a photovoltaic flat collector according to the prior art

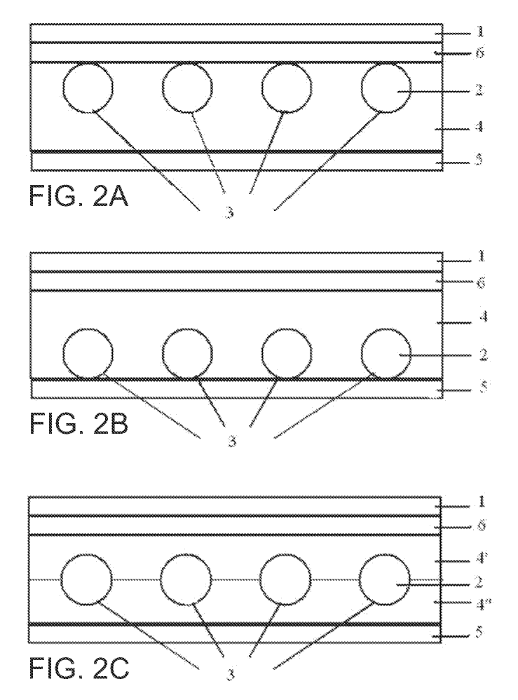

FIGS. 2a-2c show embodiments of a temperature-control body according to the invention for a photovoltaic flat collector.

FIGS. 1a and 1b show cooled photovoltaic modules according to the prior art. In the photocell layer 1, the conversion of radiation energy from the sun into electrical energy takes place. That part of the solar energy that is not converted into electrical energy occurs as heat, which leads to an increase in the temperature of the photocell layer 1. Since the yield of electrical energy, i.e. the ratio of electrical energy given off to solar energy radiated in, falls with increasing temperature of the photocell layer 1, cooling devices are provided, with the intention of preventing the photocell layer 1 from heating up beyond a certain maximum operating temperature.

Represented in FIG. 1a is a photovoltaic module with a cooling device integrated in a housing, comprising a cooling body 7 with cooling ribs, which transfer the excess heat to a temperature-control medium 2. An alternative construction according to the prior art is represented in FIG. 1b: the photocell layer 1 is in thermal contact with a heat-distributing layer 6, which transfers the excess heat to heat transfer tubes 3 through which temperature-control medium 2 flows. The heat transfer between the cooling body 7 and the heat transfer tubes 3 is produced by a linear connection 8, usually in the form of a welded or soldered joint.

FIGS. 2a to 2c show various embodiments of the temperature-control body according to the invention. The heat transfer tubes 3 through which the temperature-control medium 2 flows are embedded in a layer 4 of compressed expanded graphite.

Further functional layers 6, the function of which is explained further below, may optionally be provided between the surface of the photocell layer 1 that is facing away from the solar irradiation and the layer 4. A layer 5 of a heat-insulating material on the rear side of the layer 4 is likewise optional.

On account of its structure comprising layers lying one on top of the other, graphite is characterized by strong anisotropy of the conductivity; the electrical and thermal conductivity along the layers is significantly greater than transverse to the layers. This anisotropy is all the more pronounced the more compacted the graphite is, i.e. the more the individual graphite platelets are aligned in parallel. If, however, the graphite only undergoes slight compaction, the individual platelets are not aligned completely in parallel, and consequently the anisotropy of the conductivity is less pronounced.

The production of expanded graphite is known. Graphite interstitial compounds (graphite salts), for example graphite hydrogen sulfate, are shock-heated in a furnace or by means of microwaves. This causes the volume of the particles to increase by a factor of 200 to 400, and the bulk density to fall to 2 to 20 g/l. The expanded graphite obtained in this way comprises vermicular or concertina-like aggregates. If the expanded graphite is compacted again, the individual aggregates hook into one another to form a solid assembly, which without adding a binder can be shaped into self-supporting sheet-like formations, for example films or webs, or into moldings, for example panels. An alternative possibility, likewise known from the prior art, for producing moldings from compressed expanded graphite is that of carrying out the thermal expansion of the graphite interstitial compound or graphite salt in an appropriately designed mold. It should be noted in this case that the mold must allow gases to escape. The requirements for the purity of the expanded graphite for the component according to the invention are somewhat comparable to those for known applications of expanded graphite such as, for example, in sealing technology. Here, material with a carbon content of at least 98% is usually used. For the component according to the invention, however, expanded graphite with a lower carbon content of about 90% can also be used.

To produce the layer 4, the expanded graphite is compacted relatively less, and therefore has only relatively weak anisotropy of the thermal conductivity. When setting the compaction, a compromise must be reached between the requirement for low anisotropy on the one hand, for which lowest possible compaction is necessary, and the requirement for mechanical strength on the other hand, which is no longer reliably obtained with inadequate compaction. Layers 4 of compressed expanded graphite with a density of between 0.02 and at most 0.5 g/cm³ have proven to be particularly suitable for the use according to the invention of cooling photovoltaic modules.

Various methods are available for producing the temperature-control body according to the invention.

According to the first method, expanded graphite obtained by thermal expansion of an expandable graphite interstitial compound is compacted into a sheet-like formation. The compaction may be performed discontinuously or continuously. In the case of the discontinuous way of working, individual sheet-like formations of compacted expanded graphite are obtained. Preferably, near-net sheet-like formations are formed, i.e. panels with the dimensions desired for the temperature-control body. Otherwise, the sheet-like formations obtained must be cut to the desired dimensions. In the case of the continuous way of working, the compaction is performed in a rolling train or in a calender. In this case, an endless web of compacted expanded graphite is obtained, from which panels with the desired dimensions are cut.

In a first variant of the invention, such panels of pressed expanded graphite form the layer 4 of the temperature-control body according to the invention. On account of its low compaction, the panel material has a considerable compression reserve and readily undergoes forming. Therefore, the heat transfer tubes 3 for the temperature-control medium 2 can be easily pressed into the surface of the panel. Expanded graphite is distinguished by being highly adaptable to neighboring surfaces, so that an intimate connection, and consequently low heat transfer resistance, is ensured between the panel material and the tube wall. The pressing-in of the tubes causes the panel material to undergo compaction. The panel should therefore be of such a consistency with regard to the compacting of the expanded graphite that the density of the panel after the pressing-in of the tubes lies between 0.02 and 0.5 g/cm³.

The heat transfer tubes 3 can be pressed into the panel to such a depth that they finish flush with the surface of the panel. This embodiment is shown in FIGS. 2a and 2b. In the embodiment shown in FIG. 2a, the heat transfer tubes 3 have being pressed into the surface of the panel that is facing the solar irradiation. Between the surface of the photocell layer 1 that is facing away from the solar irradiation and the surface of the panel, further functional layers 6 may be optionally provided, the function of which is explained further below.

By contrast with this, in the embodiment that is shown in FIG. 2b the transfer tubes 3 are pressed into the rear side of the panel. The advantage of this embodiment is that a closed, continuous surface area is available for the contact with the surface of the photocell layer 1 that is facing away from the solar irradiation. On the other hand, the distance between the photocell layer 1 and the heat transfer tubes 3 that has to be overcome by heat conduction transversely to the plane of the panel is greater in this embodiment than in the embodiment according to FIG. 2a. Therefore, the graphite layer remaining between the heat transfer tubes 3 and the surface of the photocell layer 1 that is facing away from the solar irradiation should be as thin as possible. For reasons of stability, however, a residual thickness of 1 to 2 mm is required. The embedding of the heat transfer tubes 3 into the rear side of the panel is preferably used in those cases where it is possible to dispense with the optional functional layers 6, which increase the distance between the heat transfer tubes 3 and the photocell layer 1. Alternatively, the tubes may also be placed between two layers 4′, 4″ of expanded graphite lying one on top of the other and then be pressed together. The layer 4 here comprises the two layers 4′, 4″ lying one on top of the other and pressed one against the other, between which the tubes 3 are embedded (FIG. 2c). It has been found that such composite bodies comprising two pressed-together layers 4′, 4″ of compressed expanded graphite are very stable; they cannot be separated again at the boundary surface of the layers 4′, 4″. Layers (panels) of compressed expanded graphite can typically be produced with thicknesses of between 2 and 50 mm. In the temperature-control body according to the invention, the choice of panel thickness is based mainly on the diameter of the tubes to be embedded and, to the extent necessary, on stability requirements. Furthermore, it should be taken into consideration whether the embedding of the tubes should be performed in a way corresponding to FIG. 2a or 2b, into the surface of a panel, or in a way corresponding to FIG. 2c, between two layers 4′, 4″.

In an alternative method, the layer 4 is formed by thermal expansion of expandable graphite interstitial compounds (graphite salts) in an evacuable mold in which the tubes have also been placed. Either first the tubes are placed into the mold and then the mold is filled with the expandable graphite interstitial compound, or first the mold is filled, at least partially, and then the transfer tubes 3 are placed in it. In the case of this procedure, because of the thermal inertia of the mold, the heating up is preferably performed by means of microwaves. Alternatively, the mold may also be heated inductively. The layer 4 of this variant of the temperature-control body according to the invention consists of graphite expanded in the mold with heat transfer tubes 3 placed in it.

In a third variant, finally, the layer 4 is produced directly on the rear side of the photocell layer 1. For this purpose, the heat transfer tubes 3 are put in place and expanded graphite is pressed to the desired layer thickness. The amount of expanded graphite is dimensioned such that, after the compression, a material with a thickness in the range from 0.02 to 0.5 g/cm³ is obtained.

Materials known according to the prior art, i.e. mainly copper, can be used for the production of the heat transfer tubes 3. Thanks to the high thermal conductivity of the expanded graphite surrounding the tubes and the large surface area available for heat transfer between the expanded graphite of the layer 4 and the transfer tubes 3, a lower thermal conductivity of the tube material can also be accepted in the heat-transfer body according to the invention. For example, adequate heat transfer can also be achieved with plastic tubes. There is in this case the possibility of substituting the relatively expensive copper tubes by possibly less expensive and more easily workable tubes of non-metallic materials, for example of plastic or graphite-filled plastic.

If the waste heat of the photovoltaic modules is to be further used for thermal purposes, for example for providing hot water or for heating a building, the surface of the layer 4 that is facing away from the solar irradiation is optionally provided with a heat-insulating layer 5 as a rear wall. Layers of mineral fibers, polyethylene foam or plasterboard, for example, are advantageously provided for this. The heat-insulating layer 5 is attached to the side of the layer 4 that is facing away from the solar irradiation by means of being adhesively bonded or pressed on. The pressing-on of the heat-insulating layer 5 and the pressing-in of the heat transfer tubes 3 may take place in one working step if the mechanical stability of the heat-insulating material so allows.

The photocell layer 1 is, for example, applied to the layer 4, in which the heat transfer tubes 3 are already embedded. Alternatively, in the production of the temperature-control body, first a semifinished product may be produced, by the surface of the layer 4 that is facing the photocell layer 1 possibly being provided with a layer of bonding agent. The heat transfer tubes 3 are then embedded into the compressed expanded graphite layer 4 of the semifinished product.

A particularly advantageous variant of the present invention is characterized in that a layer 6 for lateral heat distribution is provided between the surface of the layer 4 of compressed expanded graphite that is facing the photocell layer 1 and the photocell layer 1. Graphite film is particularly expedient for the forming of the layer 6, since it is distinguished by a preferential heat conduction in the plane; it is therefore very well suited for laterally distributing the heat to be removed from the photocell layer 1 uniformly. Like the panels described above, graphite film is produced by compacting expanded graphite, but the degree of compaction of the expanded graphite in a graphite film is greater. The density of the graphite films used according to the invention is at least 0.5 g/cm³, preferably at least 0.7 g/cm³. With pressures that can be used in practice, a compaction of up to 2.0 g/cm³ is possible. The theoretical upper limit is given by the density of ideally structured graphite at 2.25 g/cm³. Particularly preferred is a graphite film with a density of between 1.0 and 1.8 g/cm³. The higher compaction has the effect that the layer planes in graphite film are much more strongly oriented in parallel than in the less compact and expanded graphite of the layer 4, and this results in the more pronounced anisotropy of the heat conduction in graphite film.

Owing to the relatively low thermal conductivity in the direction of the thickness, it is required that the graphite film serving for lateral heat distribution is as thin as possible. The thickness of the film should not exceed 1.5 mm; preferably, the film in layer 6 is thinner than 0.7 mm. The surface of the layer 4, in which the heat transfer tubes 3 are possibly already embedded, and the graphite film forming the layer 6 are connected to each other by laminating or adhesive bonding with an adhesive that is durably resistant at the operating temperature of the photovoltaic modules. Corresponding heat-resistant adhesives, for example based on acrylic resins, epoxy resins, polyurethanes or cyanoacrylate, are commercially available.

An adhesively bonded assembly is expediently heated up at least to operating temperature before use and kept at this temperature until any outgassing processes of the adhesive that would impair the operation of the photovoltaic module have ceased.

Particularly suitable for the production of the connection between the surface of the layer 4 and the graphite film forming the layer 6 are conductive adhesives, for example adhesives which contain conductive particles. Such adhesives are commonly used in particular for the production of electronically conducting adhesive connections and are commercially available. Since such additives that have electrical conductivity, such as for example carbon black or metal powder, are generally also distinguished by high thermal conductivity, these adhesives are also suitable for improving the thermal conductivity of the adhesive connection. However, other thermally conductive additives may also be used. A thermally conductive connection can also be produced by adding particles with high thermal conductivity, for example graphite flakes or particles obtained by grinding up graphite film, to an adhesive which, though advantageous on account of its thermal resistance, itself only has low thermal conductivity.

Alternatively, a resin or a binder that is pyrolyzed (carbonized) after connecting the graphite layer 4 and the graphite film is used as the adhesive. The residues remaining after the pyrolysis form thermally conductive carbon bridges between the mutually adjacent surfaces of the layer 4 and of the film forming the layer 6. Examples of resins or binders that can be carbonized, i.e. can be pyrolyzed while leaving behind a high carbon yield, are phenolic resins, epoxy resins, furan resins, polyurethane resins and pitches. A further advantage of this variant is that all the volatile constituents of the resin are driven out during the pyrolysis, so that during operation there is no longer any risk of outgassing. Owing to the high thermal loading during the pyrolysis, this method can only be used if the heat transfer tubes 3 have not yet been embedded in the layer 4.

Instead of conventional adhesives, it is also possible to use surface-active substances from the group comprising organo-silicon compounds, perfluorinated compounds and soaps of the metals sodium, potassium, magnesium or calcium, which are applied in a thin layer (10 to 1000 nm, preferably 100 to 500 nm) to one of the surfaces to be connected. The surface areas to be connected are brought into contact with each other and connected to each other at a temperature of between 30 and at most 400° C. and under a pressing pressure of 1 to 200 MPa. Tests have shown that this method, described in patent specification EP 0 616 884 B1 particularly for the production of connections between graphite film and metal surfaces, is also suitable for connecting two graphite surfaces. If this method is used, the heat transfer tubes 3 must be pressed into the layer 4 at the same time, since otherwise the latter is too strongly compacted.

A further advantage of the coating of the surface of the layer 4 with a layer 6 of graphite film is that graphite film is less porous than the less compacted expanded graphite of the layer 4, on account of the higher compaction of the expanded graphite, and therefore has a closed, relatively smooth surface. This ensures that a very good connection to the photocell layer 1 is achieved.

As an alternative to graphite film, a metal foil may be laminated on or adhesively attached to the surface of the layer 4 that is facing the photocell layer 1, as a functional layer 6 for the lateral heat distribution. A metal layer produced by electrolytic deposition or a metal ceramic layer produced by chemical deposition, sputtering or vapor deposition, is also suitable for the lateral heat distribution. Suitable ceramic materials for the functional layer 6 for the lateral heat distribution are, for example, silicon carbide, aluminum nitride and aluminum oxide. The functional layer 6 may also be a ceramic layer produced by pyrolysis of thin films from organic precursor compounds. Examples of ceramic layers of pyrolyzed organic precursors are silicon dioxide, silicon carbide or silicon carbonitride layers of pyrolyzed polysilanes or polysilazanes.

The present invention also relates to the provision of laminar semifinished products for the temperature-control bodies according to the invention. The semifinished products comprise a layer 4 of compressed expanded graphite with a density of between 0.02 g/cm³ and 0.5 g/cm³ or the laminate of graphite film 6 and a layer of compressed expanded graphite 4, the graphite film 6 being located between the photocell layer 1 and the layer 4 of expanded graphite. The graphite film 6 has a density of at least 0.5 g/cm³, preferably between 1.0 and 1.8 g/cm³. The graphite film 6 and the layer 4 are connected by means of one of the methods already described above for the production of the temperature-control body.

If required, the semifinished product contains a layer of bonding agent between the photocell layer 1 and the graphite film 6 or the compressed expanded graphite layer 4.

### LIST OF DESIGNATIONS

1 photocell layer
2 temperature-control medium
3 heat transfer tubes
4 layer of compressed expanded graphite
5 heat-insulating layer
6 layer for lateral heat distribution
7 cooling fins
8 linear connection

1-15. (canceled)

16. A temperature-control body for a photovoltaic module having a photocell layer with a front side facing toward a solar radiation and a rear side facing away from the solar radiation, the temperature-control body comprising:
a layer of compressed expanded graphite;
heat transfer tubes for conducting a temperature-control medium embedded in said layer of compressed expanded graphite, said heat transfer tubes being connected to the rear side of the photocell layer facing away from the solar irradiation.

17. The temperature-control body according to claim 16, wherein a density of said compressed expanded graphite in said layer lies in a range from 0.02 g/cm³ to 0.5 g/cm³.

18. The temperature-control body according to claim 16, wherein said layer consists of expanded graphite pressed to form a plate.

19. The temperature-control body according to claim 18, wherein said heat transfer tubes are embedded in a surface of said layer of compressed expanded graphite facing the photocell layer and said heat transfer tubes finish flush with said surface of said layer.

20. The temperature-control body according to claim 16, wherein said layer of compressed expanded graphite comprises two layers lying on top of one another and pressing against one another, and said heat transfer tubes are embedded in between said two layers.

21. The temperature-control body according to claim 16, wherein said heat transfer tubes consist of a nonmetallic material.

22. The temperature-control body according to claim 21, wherein said heat transfer tubes plastic tubes.

23. The temperature-control body according to claim 16, which comprises a heat-insulating layer disposed on a surface of said layer facing away from the photocell layer.

24. The temperature-control body according to claim 23, wherein said heat-insulating layer comprises mineral fiber panels, polyurethane foam, or plasterboard.

25. The temperature-control body according to claim 16, which comprises a layer for lateral heat distribution provided between a surface of said layer facing the photocell layer and the photocell layer.

26. The temperature-control body according to claim 25, wherein said layer for lateral heat distribution is a metal layer, a metal foil, or a graphite film that is vapor-deposited, sputtered-on, or electrolytically or chemically deposited.

27. The temperature-control body according to claim 26, wherein said layer for lateral heat distribution is a ceramic layer that is vapor-deposited, sputtered-on, or produced by pyrolysis from organic precursor compounds.

28. The temperature-control body according to claim 26, wherein said layer for lateral heat distribution is a graphite film with a density of at least 0.5 g/cm³ and a thickness of at most 1.5 mm.

29. The temperature-control body according to claim 28, wherein said layer for lateral heat distribution has a density of at least 1 g/cm³ and a thickness of no more than 0.7 mm.

30. The temperature-control body according to claim 28, wherein said graphite film of said layer for lateral heat distribution is connected to the surface of said layer facing the photocell layer by one of the following means:
an adhesive;
an adhesive with heat-conducting particles of metal, carbon black, graphite flocks or ground graphite film or other heat-conducting materials dispersed in it;
carbonization residues of a phenolic resin, epoxy resin, polyurethane resin, furan resin, pitch or some other resin or binder that can be carbonized;
a surface-active substance from the group consisting of organo-silicon compounds, perfluorinated compounds, and soaps of the metals sodium, potassium, magnesium or calcium;
a lamination.

31. A laminar semifinished product, comprising a layer of compressed expanded graphite with a density of between 0.02 g/cm³ and 0.5 g/cm³.

32. A laminar semifinished product, comprising a layer of graphite film having a density of between 0.5 and 2.0 g/cm³.

33. The laminar semifinished product according to claim 32, wherein the graphite film has a density of between 1.0 and 1.8 g/cm³.
